(19) United States
(12) Patent Application Publication
(10) Pub. No.: US 2004/0062076 A1
(43) Pub. Date: Apr. 1, 2004

(54) FLASH MEMORY STRUCTURE AND METHOD OF FABRICATION

(76) Inventors: Ching-Hsiang Hsu, Hsin-Chu City (TW); Ching-Sung Yang, Chang-Hua Hsien (TW); Shih-Jye Shen, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 10/249,215

(22) Filed: Mar. 24, 2003

(30) Foreign Application Priority Data
Sep. 26, 2002 (TW) 091122234

(51) Int. Cl. G11C 16/04; G11C 5/02

(52) U.S. Cl. 365/185.05; 365/63; 365/51

(57) ABSTRACT

A flash memory structure and method of fabrication is introduced. The flash memory structure includes a plurality of parallel word lines positioned on a semiconductor substrate, a plurality of parallel source lines with first conductivity type positioned perpendicularly to the word lines and within the semiconductor substrate, two bit lines with first conductivity type positioned on two sides of each source line and within the semiconductor substrate, a doped region with second conductivity type positioned beneath and surrounding each bit line, a contact plug positioned in each bit line for electrically connecting to the bit line and a corresponding doped region beneath and surrounding the bit line, and a gate positioned on an overlapped region of the semiconductor substrate and each word line.

### BACKGROUND OF INVENTION

1. Field of the Invention

The present invention relates to a non-volatile memory structure and method of fabrication, and more particularly, to a contactless channel program/erase flash memory structure and method of fabricating the same.

2. Description of the Prior Art

Non-volatile memory devices, such as electrically erasable programmable read only memories (EEPROMs) or flash memories have been used widely since they have beneficial functions of storing data in a non-volatile manner permanently, and repeating certainly being reprogrammed or erased many times. Generally, the flash memory structure is identical to the EEPROM device. However, the flash memory can be programmed and erased data a block at a time instead of a byte at a time of the EEPROM, and this dramatically reduces memory access time of the memory devices.

Please refer to FIG. 1, which is a cross-sectional view illustrating a conventional flash memory cell 10. As shown in FIG. 1, the flash memory cell 10 includes a stacked gate 14 formed on a P-type semiconductor substrate 12, an N-type source 16 and an N-type drain 18 formed two sides of the stacked gate 14 in the semiconductor substrate 12 respectively, and a P-type doped region 20 formed surrounding and beneath the drain 18 in the semiconductor substrate 12. Typically, the stacked gate 14 is composed of a tunnel oxide layer 22, a floating gate 24, an insulating layer 26, and a control gate 26 formed between the source 16 and the drain 18 on the semiconductor substrate 12, respectively.

When a high voltage is applied to the control gate 28, and a low voltage is applied to the drain 18, due to the channel hot electrons (CHE) effect, electrons (e⁻) generated from a junction between the drain 18 and the doped region 20 penetrate the tunnel oxide layer 22 and eject to the floating gate 24 to raise a threshold voltage of the flash memory cell 10, and the flash memory cell 10 is programmed. Likewise, when a low voltage is applied to the control gate 28 or the control gate 28 is grounded, and a high voltage is applied to the drain 18, due to the edge Fowler-Nordheim (FN) tunneling mechanism, the electrons inside the floating gate 24 are removed to reduce the threshold voltage of the flash memory cell 10, and the flash memory cell 10 is erased.

Since demands of small size portable electronic products, such as personal digital assistants (PDAs) or mobile phones increase day by day, thereby improving quality of the flash memory and increasing memory packing density or integration of the memory devices are very important issues in the flash memory development.

### SUMMARY OF INVENTION

It is therefore a primary objective of the present invention to provide a contactless channel program/erase flash memory for increasing the memory packing density of the flash memory.

It is another object of the present invention to provide a SONOS flash memory structure for improving electrical performance of the flash memory.

According to the claimed invention, the flash memory structure comprises a plurality of parallel word lines positioned on a semiconductor substrate, a plurality of parallel source lines with first conductivity type positioned within the semiconductor substrate, two bit lines with first conductivity type positioned on two sides of each source line and within the semiconductor substrate, the source lines and the bit lines being perpendicular to the word lines, a doped region with second conductivity type positioned beneath and surrounding each bit line, a contact plug positioned in each bit line for electrically connecting to the bit line and a corresponding doped region beneath and surrounding the bit line, and a oxide-nitride-oxide (ONO) dielectric layer positioned on an overlapped region of the semiconductor substrate and each word line.

The flash memory structure of the present invention utilizes the nitride layer of the ONO dielectric layer that has an ability of trapping electric charges easily, to store data effectively. In addition, the flash memory structure utilizes only one contact plug electrically connected to each bit line to control data access of corresponding flash memory cells defined in each bit line of the flash memory structure. Therefore, each flash memory cell does not need an individual contact plug, and so as to prevent a misalignment problem during fabricating the contact plug, even more reduce size of each flash memory cell, and increase integration of the flash memory structure.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a cross-sectional view illustrating a conventional flash memory cell.

FIG. 2 is atop view illustrating a flash memory according to the present invention.

FIG. 3 is a cross-sectional view illustrating of the flash memory along line 1-1 shown in FIG. 2.

FIG. 4 is a front side view illustrating the flash memory along line 11-11 shown in FIG. 2.

FIG. 5 to FIG. 9 are cross-sectional views illustrating the fabrication process of the flash memory according to the present invention.

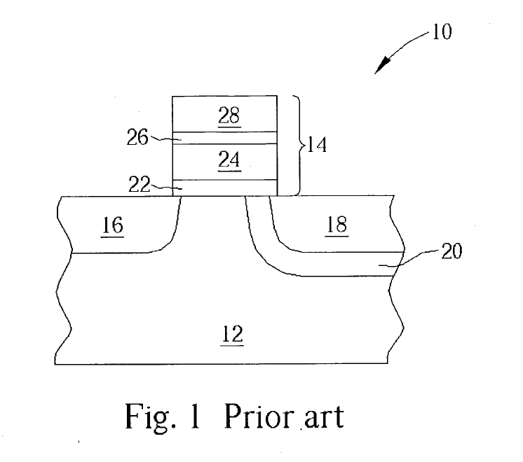

### DETAILED DESCRIPTION

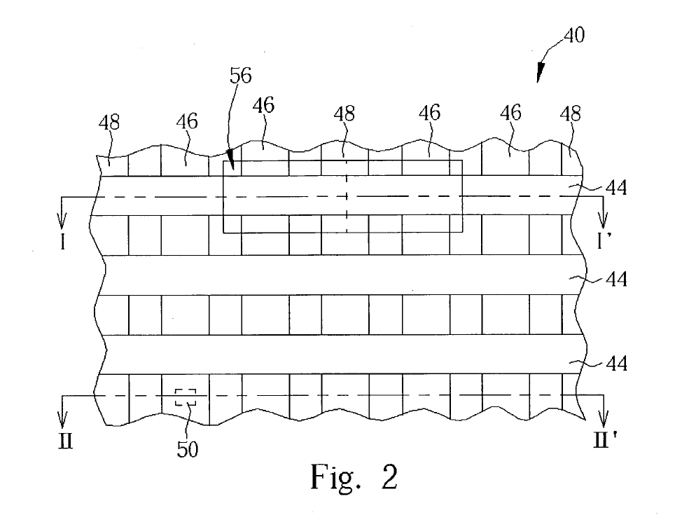

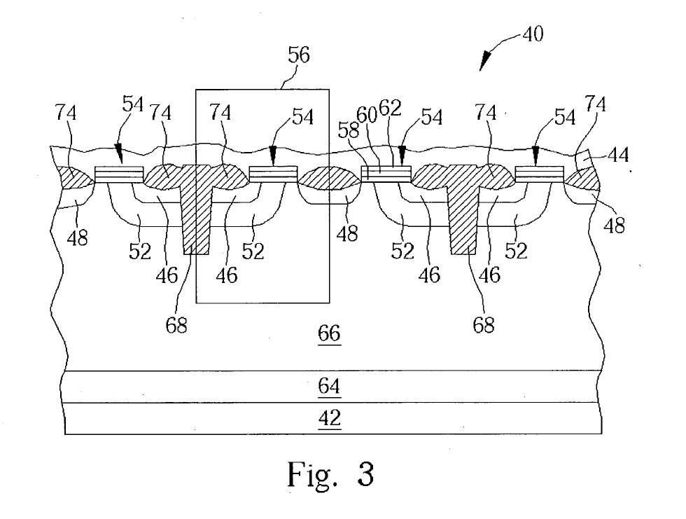

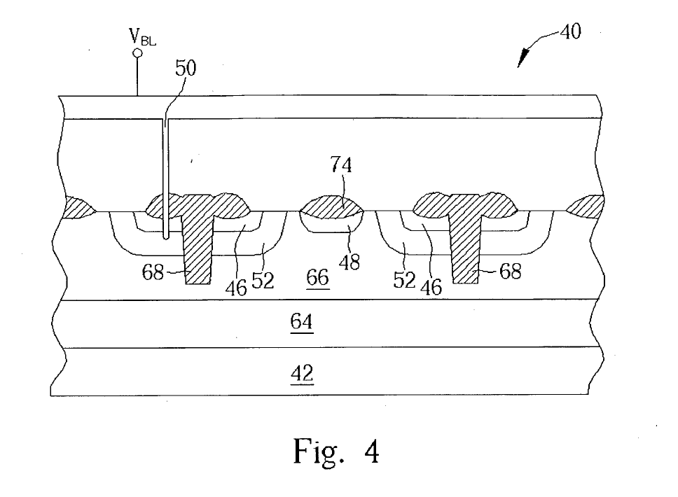

Please refer to FIG. 2 to FIG. 4. FIG. 2 is a top view illustrating a flash memory 40 according to the present invention. FIG. 3 is a cross-sectional view illustrating of the flash memory 40 along line I-I shown in FIG. 2. FIG. 4 is a front side view illustrating the flash memory 40 along line II-II shown in FIG. 2. In the preferred embodiment of the present invention, a BiNOR SONOS flash memory is utilized as an example. But the present invention is not limited in this, various types of flash memories can be applied in the present invention. As shown in FIG. 2 and FIG. 3, the flash memory 40 includes a plurality of parallel word lines 44 formed on a semiconductor substrate 42, a plurality of parallel buried bit lines 46 formed in a semiconductor substrate 42, a plurality of buried source lines 48 formed in a semiconductor substrate 42, and a contact plug 50 formed in each bit line 46. Generally, the bit lines 46 and the source lines 48 are perpendicular to the word lines 44.

Furthermore, the flash memory 46 is composed of a plurality of contactless channel program/erase flash memory cells 56, and each flash memory cell 56 includes a word line 44, two bit lines 46 overlapped with the word line 44, and a common source line 48. Moreover, a plurality of shallow trench isolations (STIs) 68 formed in the semiconductor substrate 42 are utilized to isolate the flash memory cells 56. In addition, each flash memory cell 56 further includes a doped region 52 that has a different conductive type from the bit lines 46 formed surrounding and beneath a corresponding bit line 46 to prevent from generating abnormal punch-through phenomenon between a source and a drain of each flash memory cell 56, a self-aligned thermal oxide (SATO) layer 74 formed on the bit line 46 and the source line 48 to prevent from generating electricity disturbance, and a charge storage region 54 composed of the ONO dielectric layer formed on the semiconductor substrate 42 between the bit line 46 and the source line 48 and covering a portion of the bit line 46 and the doped region 52.

As shown in FIG. 4, each bit line 46 utilizes only one contact plug 50 to electrically connect to the underlying doped region 52. For example, the contact plug 50 can penetrate a PN junction of the bit line 46 and the corresponding doped region 52 beneath and surrounding the bit line 46, or the contact plug 50 can cover a surface of the bit line 46 and a surface of the corresponding underlying doped region 52. Therefore, a bit line voltage V_{BL} can be applied through the contact plug 50 to the corresponding bit line 46 and the underlying doped region 52 simultaneously, and electrons can be programmed or erased through an overlapped region between the charge storage region 54, the bit line 46, and the doped region 52.

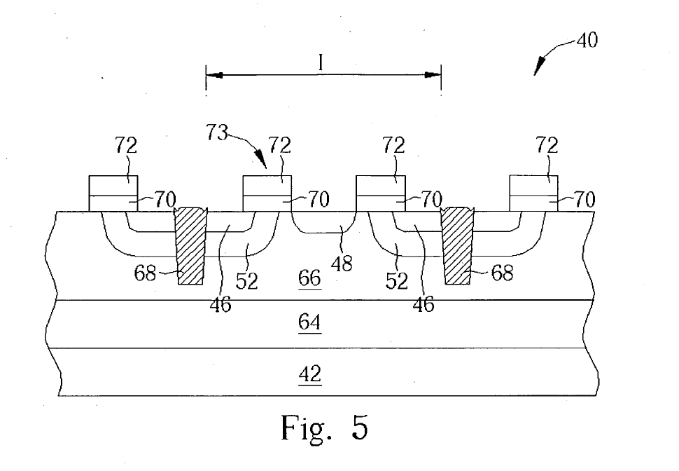

Furthermore, the present invention provides a fabricating method of the flash memory 40. Please refer to FIG. 5 to FIG. 9, which are cross-sectional views illustrating the fabrication process of the flash memory 40 according to the present invention. As shown in FIG. 5, a plurality of field oxide layers (not shown in FIG. 5) or shallow trench isolations 68 are formed in a N-type semiconductor substrate 42 to define a plurality of active areas I on the semiconductor substrate 42. Then, a deep P-type well 64 and a N-type well 66 are formed in the semiconductor substrate 42 by implanting P-type and N-type dopants, respectively. Further, a pad oxide layer 70 and a silicon nitride layer 72 are formed on the well 66, and a photo etching process (PEP) is performed to remove a portion of the silicon nitride layer 72 and the pad oxide layer 70 to form a plurality of hard masks 73. After that, a first ion implantation process is performed to implant N-type dopants, such as arsenic (As) ions, to form a plurality of N⁺-type doped regions functioning as a drain 46 and a source 48 of the flash memory cell 56, respectively in the well 66 not covered by the hard masks 73. Afterwards, a patterned mask (not shown in FIG. 5) is formed on the well 66 to cover the source 48, and a second ion implantation process is performed to implant P-type dopants, such as fluoride boron (BF₂), to form a plurality of P-type pocket doped regions 52 not covered by the patterned mask and surrounding beneath the drains 46, and then the patterned mask is removed.

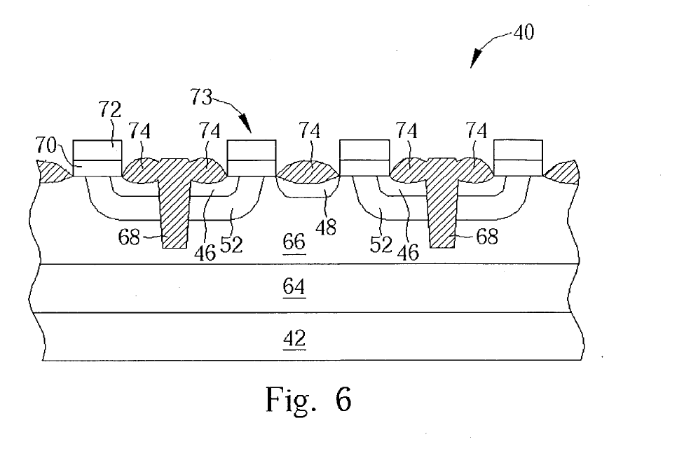

As shown in FIG. 6, a thermal oxidization process is performed to form a plurality of self-aligned thermal oxide (SATO) layers on the drains 46 and the sources 48 not covered by the hard masks 73. The SATO layers are used to prevent from generating current leakage and affecting the electrical performance of the flash memory 40.

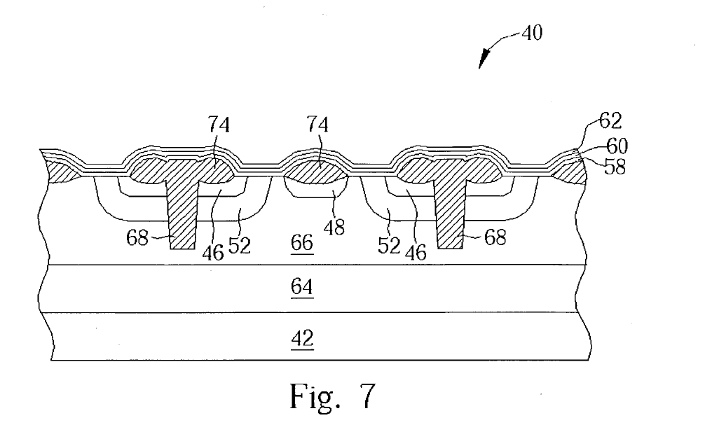

Then as shown in FIG. 7, a chemical vapor deposition (CVD) process is performed to form an ONO dielectric layer that composed of a silicon oxide layer 58, a nitride layer 60, and a silicon oxide layer 62. Typically, the silicon oxide layer 58 has a thickness of approximately 2 nanometers (nm) and below, the nitride layer 60 has a thickness of approximately 10 nm, and the silicon oxide layer 62 has a thickness of approximately 3 to 4 nm.

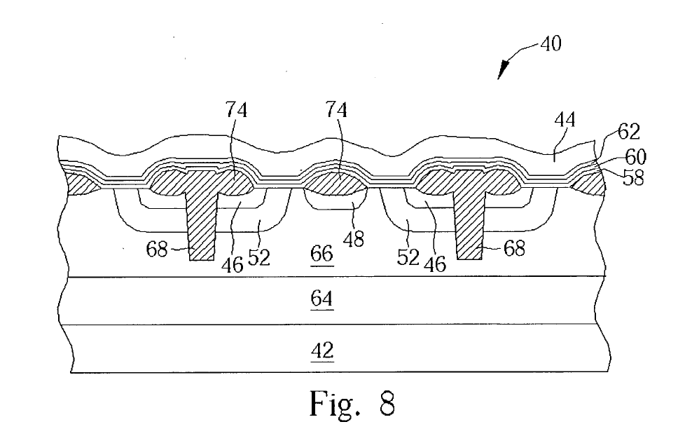

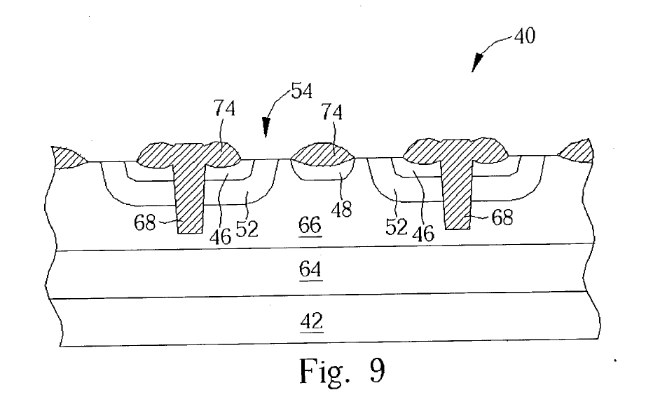

As shown in FIG. 8 and FIG. 9, a polysilicon layer 44 that has a thickness of approximately 200 nm is deposited on the semiconductor substrate 42, and a PEP is performed to remove a portion of the polysilicon layer 44 and the ONO dielectric layer 58, 60, 62 to form a plurality of word lines 44 on the semiconductor substrate 42, thereby defining a plurality of control gates of the flash memory cells 56 as shown in FIG. 2. In addition, the control gates can be composed of various materials, such as N-type doped polysilicon, aluminum (Al) metal, silicide (TiSi2), or P-type heavily doped polysilicon. Thereafter, another PEP is performed to form a via hole (not shown in FIG. 9) penetrating a junction of each drain 46 and the underlying doped region 52, and then a conductive material is filled with the via hole to form a plurality of contact plugs 50 in the drains 46, thereby short-circuiting the drains 46 of the flash memory cells 56 and into the underlying doped region 52 together. Consequently, a bit line voltage VBL can be applied to the drain 46 and the underlying doped region 52 as shown in FIG. 4.

The present invention utilizes the FN tunneling mechanism to program or erase the flash memory cells 56. During a programming operation of the flash memory cell 56, a high voltage is applied to the word line 44, such as 3 to 7 Volts, and a voltage lower than the word line voltage is applied to the bit line 46, such as −7 to −3 Volts, and voltage of the source line 48 remains in a floating state. Likewise, during an erasing operation of the flash memory cell 56, a low voltage is applied to the word line 44, such as −7 to −3 Volts, and a voltage higher than the word line voltage is applied to the bit line 46, such as 3 to 7 Volts, and voltage of the source line 48 remains in a floating state. Beside, during a reading data operation of the flash memory cell 56, a voltage is applied to the word line 44, such as 1 to 5 Volts, a voltage lower than the word line voltage is applied to the bit line 46, such as 0.5 to 2 Volts, and voltage of the source line 48 remains in a floating state.

To sum up, the flash memory 40 of the present invention is composed of a plurality of contactless channel program/erase flash memory cells 56, and each has a buried common source line 48 to raise integration of the flash memory 40 effectively. In addition, the flash memory 40 of the present invention utilizes each buried bit line 46 to connect the drains of the corresponding flash memory cells 56, so that only one contact plug 50 has to be utilized for short-circuiting the drains of the corresponding flash memory cells 56 and the underlying doped regions 52. Consequently, the operating velocity of the flash memory can be improved. Furthermore, the contact plugs 50 can be formed in an end of each bit lines 46. Therefore, the contact plugs 50 are not in touch with the word lines 44 due to the misalignment phenomenon caused by the fabricating processes, and the electricity disturbance generated by the contact plugs 50 and the word lines 44 can be avoided.

In comparison with the conventional flash memory, the contactless SONOS flash memory structure of the present invention utilizes the ONO dielectric layer as the floating gate, and the densified nitride layer is used to store data for reducing generating current leakage. In addition, the flash memory structure utilizes only one contact plug electrically connected to each bit line to control data access of corresponding flash memory cells defined in each bit line of the flash memory structure. Therefore, each flash memory cell does not need an individual contact plug, thereby preventing the misalignment problem during fabricating the contact plug, even more reducing size of each flash memory cell, and increasing integration of the flash memory structure.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A flash memory structure positioned on a semiconductor substrate, the flash memory structure comprising:
a plurality of parallel word lines positioned on the semiconductor substrate;
a plurality of parallel source lines with first conductivity type positioned within the semiconductor substrate;
two bit lines with first conductivity type positioned on two sides of each source line and within the semiconductor substrate, the source lines and the bit lines being perpendicular to the word lines;
a doped region with second conductivity type positioned beneath and surrounding each bit line;
a contact plug positioned in each bit line for electrically connecting to the bit line and a corresponding doped region beneath and surrounding the bit line; and
a oxide-nitride-oxide (ONO) dielectric layer positioned on an overlapped region of the semiconductor substrate and each word line.

2. The flash memory structure of claim 1 wherein the word lines are used to define a plurality of control gates of the flash memory structure.

3. The flash memory structure of claim 1 wherein the ONO dielectric layer is used to define a charge storage region of the flash memory structure.

4. The flash memory structure of claim 1 wherein the first conductivity type is N type, and the second conductivity type is P type.

5. The flash memory structure of claim 1 wherein the first conductivity type is P type, and the second conductivity type is N type.

6. The flash memory structure of claim 1 wherein a self-aligned thermal oxide (SATO) layer is formed on each bit line and each source line to prevent from generating electrical disturbance.

7. The flash memory structure of claim 1 wherein the flash memory structure is composed of a plurality of contactless channel program/erase flash memory cells.

8. The flash memory structure of claim 7 wherein each flash memory cell is composed of a source line and bit lines positioned two sides of the source line.

9. The flash memory structure of claim 8 wherein the semiconductor substrate further comprises a plurality of shallow trench isolation (STI) structures to isolate the flash memory cells.

10. The flash memory structure of claim 1 wherein the contact plug penetrates a junction of each bit line and a corresponding doped region beneath and surrounding the bit line.

11. The flash memory structure of claim 1 wherein the contact plug covers a surface of each bit line and a surface of a corresponding doped region beneath and surrounding the bit line.

12. A method for forming a flash memory structure on a semiconductor substrate, the method comprising:
forming a plurality of parallel source lines with first conductivity type within the semiconductor substrate;
forming two bit lines with first conductivity type on two sides of each source line and within the semiconductor substrate;
forming a doped region with second conductivity type beneath and surrounding each bit line;
forming a plurality of oxide-nitride-oxide (ONO) dielectric layers on the semiconductor substrate, and each ONO dielectric layer covering a channel of a corresponding bit line and each source line;
forming a plurality of word lines on the semiconductor substrate and covering the ONO dielectric layers; and
forming a contact plug in each bit line for electrically connecting to the bit line and a corresponding doped region beneath and surrounding the bit line.

13. The method of claim 12 further comprising anoxidation process for forming a self-aligned thermal oxide (SATO) layer on each bit line and each source line to prevent from generating electrical disturbance.

14. The method of claim 12 wherein the word lines are used to define a plurality of control gates of the flash memory structure.

15. The method of claim 12 wherein the ONO dielectric layers are used to define a plurality of charge storage regions of the flash memory structure.

16. The method of claim 12 wherein the first conductivity type is N type, and the second conductivity type is P type.

17. The method of claim 12 wherein the first conductivity type is P type, and the second conductivity type is N type.

18. The method of claim 12 wherein the semiconductor substrate further comprises a plurality of shallow trench isolation (STI) structures formed within the semiconductor substrate to isolate adjacent bit lines.

19. The method of claim 12 wherein the flash memory structure is composed of a plurality of contactless channel program/erase flash memory cells.

20. The method of claim 12 wherein the contact plug electrically connects each bit line with a corresponding doped region beneath and surrounding the bit line.

21. A flash memory structure positioned on a semiconductor substrate, the flash memory structure comprising:
a well formed in the semiconductor substrate with first conductivity type;
a plurality of parallel word lines positioned on the said well;
a plurality of parallel source lines with first conductivity type positioned within the said well;
two bit lines with first conductivity type positioned on two sides of each source line and within the said well, the source lines and the bit lines being perpendicular to the word lines;
a doped region with second conductivity type positioned beneath and surrounding each bit line;
a contact plug positioned in each bit line for electrically connecting to the bit line and a corresponding doped region beneath and surrounding the bit line; and
a oxide-nitride-oxide (ONO) dielectric layer positioned on an overlapped region of the said well and each word line.

22. The flash memory structure of claim 21 wherein the word lines are used to define a plurality of control gates of the flash memory structure.

23. The flash memory structure of claim 21 wherein the ONO dielectric layer is used to define a charge storage region of the flash memory structure.

24. The flash memory structure of claim 21 wherein the first conductivity type is N type, and the second conductivity type is P type.

25. The flash memory structure of claim 21 wherein the first conductivity type is P type, and the second conductivity type is N type.

26. The flash memory structure of claim 21 wherein a self-aligned thermal oxide (SATO) layer is formed on each bit line and each source line to prevent from generating electrical disturbance.

27. The flash memory structure of claim 21 wherein the flash memory structure is composed of a plurality of contactless channel program/erase flash memory cells.

28. The flash memory structure of claim 27 wherein each flash memory cell is composed of a source line and bit lines positioned two sides of the source line.

29. The flash memory structure of claim 28 wherein the semiconductor substrate further comprises a plurality of shallow trench isolation (STI) structures to isolate the flash memory cells.

30. The flash memory structure of claim 21 wherein the contact plug penetrates a junction of each bit line and a corresponding doped region beneath and surrounding the bit line.

31. The flash memory structure of claim 21 wherein the contact plug covers a surface of each bit line and a surface of a corresponding doped region beneath and surrounding the bit line.

32. A method for forming a flash memory structure on a semiconductor substrate, the method comprising:
forming a well with first conductivity type, forming a plurality of parallel source lines with first conductivity type within the said well;
forming two bit lines with first conductivity type on two sides of each source line and within the said well;
forming a doped region with second conductivity type beneath and surrounding each bit line;
forming a plurality of oxide-nitride-oxide (ONO) dielectric layers on the said well, and each ONO dielectric layer covering a channel of a corresponding bit line and each source line;
forming a plurality of word lines on the said well and covering the ONO dielectric layers; and
forming a contact plug in each bit line for electrically connecting to the bit line and a corresponding doped region beneath and surrounding the bit line.
